(19) United States
(12) Patent Application Publication
(10) Pub. No.: US 2025/0364289 A1
(43) Pub. Date: Nov. 27, 2025

(54) SUBSTRATE PROCESSING SYSTEM AND TROLLEY

(71) Applicant: Tokyo Electron Limited, Tokyo (JP)

(72) Inventors: Masahiro DOGOME, Miyagi (JP); Masatomo KITA, Miyagi (JP)

(73) Assignee: Tokyo Electron Limited, Tokyo (JP)

(21) Appl. No.: 19/289,142

(22) Filed: Aug. 4, 2025

Related U.S. Application Data
(63) Continuation of application No. PCT/JP2024/003012, filed on Jan. 31, 2024.

(30) Foreign Application Priority Data
Feb. 13, 2023 (JP) 2023-020311

(51) Int. Cl. H01L 21/677; H01L 21/683

(52) U.S. Cl. CPC H01L 21/67706; H01L 21/67724; H01L 21/67736; H01L 21/6838

(57) ABSTRACT

Provided is a substrate processing system including: a vacuum transferer having a first side surface, a second side surface on a side opposite to the first side surface, and a bottom surface having an opening, the vacuum transferer having a distance from the opening to the first side surface larger than a distance from the opening to the second side surface, first substrate processors on a first side surface side, second substrate processors on a second side surface side, a lower space defined below the vacuum transferer, a transfer robot detachably attached to the vacuum transferer to close an opening and configured to be taken out from the opening into the lower space, a first rail attached to the first substrate processors to extend along a longitudinal direction in the lower space, and a second rail attached to the second substrate processors.

### CROSS-REFERENCE TO RELATED APPLICATIONS

This application is a bypass continuation application of international application No. PCT/JP2024/003012 having an international filing date of Jan. 31, 2024 and designating the United States, the international application being based upon and claiming the benefit of priority from Japanese Patent Application No. 2023-020311, filed on Feb. 13, 2023, the entire contents of each are incorporated herein by reference.

### TECHNICAL FIELD

The present disclosure relates to a substrate processing system and a trolley.

### BACKGROUND

PTL 1 discloses a system including a wafer transfer assembly that includes a robot therein configured to engage, lift, and transfer a wafer, processing modules connected to the wafer transfer assembly, and a service tunnel defined below the wafer transfer assembly. The service tunnel provides access to undersides of a wafer transfer module to repair the robot.

PTL 2 discloses a substrate processing system including processing chambers and power source system units disposed below the processing chambers, respectively, and individually supplying power to the processing chambers. In the substrate processing system disclosed in PTL 2, during maintenance, a unit to be maintained is lifted by a crane and transferred along a rail disposed to protrude outward from an end of the processing chamber.

### CITATION LIST

### Patent Documents

PTL 1: JP2017-092459A
PTL 2: JP2021-034495A

### SUMMARY

A technique according to the present disclosure provides a substrate processing system in which a unit can be accessed from below a vacuum transfer module and a trolley that can be appropriately moved to below the vacuum transfer module with a transfer robot provided in the vacuum transfer module placed thereon.

An aspect of the present disclosure is a substrate processing system including: a vacuum transfer module extending along a longitudinal direction of the substrate processing system, the vacuum transfer module having a first side surface, a second side surface on a side opposite to the first side surface, and a bottom surface, the bottom surface having an opening, a distance from the opening to the first side surface being larger than a distance from the opening to the second side surface, substrate processing modules including first substrate processing modules connected to the first side surface of the vacuum transfer module and second substrate processing modules connected to the second side surface of the vacuum transfer module, a lower space defined between the first substrate processing modules and the second substrate processing modules below the vacuum transfer module, a transfer robot detachably attached to the vacuum transfer module to close the opening, configured to transfer a substrate in the vacuum transfer module, and configured to be taken out from the opening into the lower space, a first rail attached to the first substrate processing modules to extend along the longitudinal direction in the lower space, and a second rail attached to the second substrate processing modules to extend along the longitudinal direction in the lower space.

According to the present disclosure, a substrate processing system in which a unit can be accessed from below a vacuum transfer module and a trolley that can be appropriately moved to below the vacuum transfer module with a transfer robot provided in the vacuum transfer module placed thereon can be provided.

### BRIEF DESCRIPTION OF DRAWINGS

FIG. 1 is a plan view illustrating an example of a configuration of a substrate processing system according to an embodiment.

FIG. 2 is a perspective view illustrating an example of the configuration of the substrate processing system according to the present embodiment.

FIG. 3 is a cross-sectional view illustrating an example of the configuration of the substrate processing system according to the present embodiment.

FIG. 4 is a cross-sectional view illustrating an example of the configuration of the substrate processing system according to the present embodiment.

FIG. 5 is a perspective view illustrating an example of a configuration of a substrate transfer robot.

FIG. 6 is an explanatory diagram illustrating an example of configurations of a substrate processing module and a post-processing module.

FIG. 7 is a perspective view illustrating an example of a configuration of a trolley on which the substrate transfer robot is placed and transferred.

FIG. 8 is an explanatory diagram illustrating a main step related to loading of the substrate transfer robot into the vacuum transfer module.

FIG. 9 is an explanatory diagram illustrating a main step related to the loading of the substrate transfer robot into the vacuum transfer module.

FIG. 10 is an explanatory diagram illustrating a main step related to the loading of the substrate transfer robot into the vacuum transfer module.

FIG. 11 is an explanatory diagram illustrating a main step related to the loading of the substrate transfer robot into the vacuum transfer module.

FIG. 12 is an explanatory diagram illustrating a main step related to the loading of the substrate transfer robot into the vacuum transfer module.

FIG. 13 is an explanatory diagram illustrating a main step related to the loading of the substrate transfer robot into the vacuum transfer module.

FIG. 14 is an explanatory diagram illustrating a jig attached to a frame that supports the vacuum transfer module.

FIG. 15 is an explanatory diagram illustrating a state of the trolley entering a lower space after the jig is attached.

### DETAILED DESCRIPTION

In a step of producing a semiconductor device, an inside of a substrate processing module accommodating a semiconductor substrate (hereinafter, simply referred to as a “substrate”) is brought into a pressure-reduced (vacuum) state, and various types of plasma processing such as etching processing and post-processing are performed on the substrate. The plasma processing is performed by using a processing system including a vacuum transfer module that transfers the substrate under reduced pressure and the substrate processing modules disposed adjacent to the vacuum transfer module.

PTL 1 discloses that providing access to the undersides of the wafer transfer module through the service tunnel to repair the robot disposed in the wafer transfer assembly, but does not describe or suggest loading or unloading the robot itself from the undersides of the wafer transfer module. PTL 2 also does not describe or suggest loading or unloading the substrate transfer robot into or from the vacuum transfer module.

A technique according to the present disclosure has been made in view of the above-described circumstances and provides a substrate processing system in which a unit can be accessed from below a vacuum transfer module and a trolley that can be appropriately moved to below the vacuum transfer module with a transfer robot provided in the vacuum transfer module placed thereon. Hereinafter, a substrate processing system according to the present embodiment will be described with reference to the drawings. The same reference numerals will be given to elements having substantially the same functional configurations throughout the specification and the drawings, and redundant description thereof will be omitted.

### <Substrate Processing System>

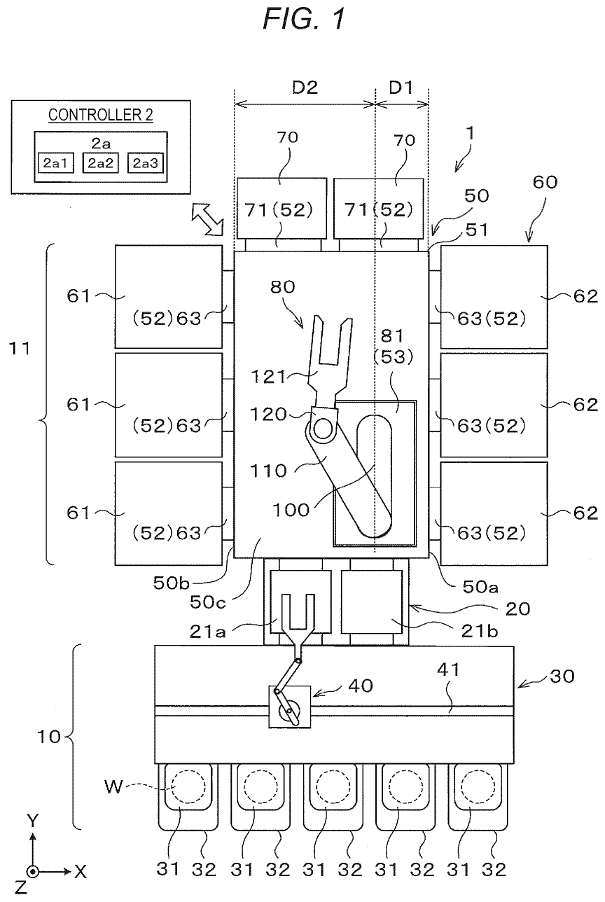

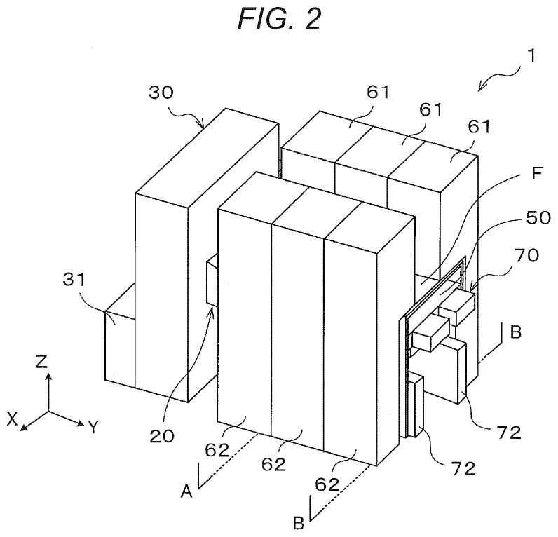

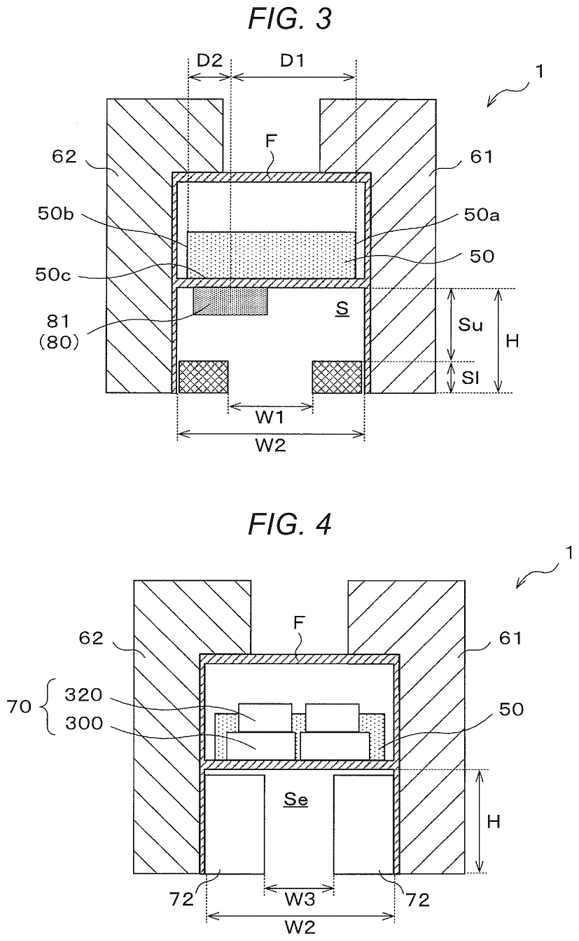

First, a configuration of the substrate processing system according to the present embodiment will be described. FIGS. 1 and 2 are plan view and perspective view, respectively, illustrating a schematic configuration of a substrate processing system 1 according to the present embodiment. FIGS. 3 and 4 are cross-sectional views illustrating, respectively, an A cross-section and a B cross-section of the perspective view of the substrate processing system 1 illustrated in FIG. 2. A wafer is an example of a substrate.

As illustrated in FIG. 1, the substrate processing system 1 has a configuration in which an atmospheric portion 10 and a decompression portion 11 are integrally connected through a load-lock module 20. The atmospheric portion 10 includes an atmospheric module that processes and/or transfers a substrate W under an atmospheric atmosphere. The decompression portion 11 includes a decompression module (vacuum module) that processes and/or transfers the substrate W in a decompressed (vacuum) atmosphere.

The load-lock module 20 includes a plurality of, for example, two load-lock chambers 21a and 21b along an atmospheric transfer module 30 to be described later and a vacuum transfer module 50 (i.e., vacuum transferer) to be described later in the present embodiment. In one embodiment, the load-lock module 20 (i.e., load-lock) includes the two load-lock chambers 21a and 21b arranged along a first horizontal direction.

The load-lock chambers 21a and 21b (hereinafter, collectively referred to as the “load-lock chamber 21”) are provided to communicate an interior space of the atmospheric transfer module 30 to be described later of the atmospheric portion 10 and an interior space of the vacuum transfer module 50 to be described later of the decompression portion 11 through a substrate transfer port. Substrate transfer ports 22 and 23 are configured to be opened and closed by gate valves 24 and 25, respectively.

The load-lock chamber 21 is configured to temporarily hold the substrate W. The load-lock chamber 21 is configured such that an interior thereof can be switched between an atmospheric atmosphere and a vacuum environment (vacuum state). That is, the load-lock module 20 is configured to appropriately transfer the substrate W between the atmospheric portion 10 in an atmospheric atmosphere and the decompression portion 11 in the vacuum environment.

The atmospheric portion 10 includes the atmospheric transfer module 30 including a substrate transfer robot 40 to be described later therein, and load ports 32 placed with hoops 31 capable of storing the substrates W. An orienter module (not illustrated) that adjusts an orientation of the substrate W in the horizontal direction, a storage module (not illustrated) that stores the substrates W, and the like may be provided adjacent to the atmospheric transfer module 30.

The atmospheric transfer module includes a housing having rectangular interior, and an interior of the housing is maintained in the atmospheric atmosphere. A plurality of, for example, five load ports 32 are disposed in parallel on one side surface forming a long side of the atmospheric transfer module 30 on a Y-axis negative direction side. The load-lock chambers 21a and 21b of the load-lock module 20 are disposed in parallel on the other side surface forming a long side of the atmospheric transfer module 30 on a Y-axis positive direction side.

The substrate transfer robot 40 that transfers the substrate W is provided inside the atmospheric transfer module 30. For example, the substrate transfer robot 40 is configured to move on a transfer path 41 extending in an X-axis direction and transfer the substrate W between the hoop 31 of the load port 32 and the load-lock chambers 21a and 21b of the load-lock module 20. A configuration of the substrate transfer robot 40 is not limited thereto.

The decompression portion 11 includes the vacuum transfer module 50 that transfers the substrate W therein, the load-lock module 20, a substrate processing module 60 (i.e., substrate processor) that performs desired processing on the substrate W transferred from the vacuum transfer module 50, and a post-processing module 70 (i.e., post processor) that performs post-processing on the substrate W subjected to desired processing by the substrate processing module 60. An interior of each of the vacuum transfer module 50, the substrate processing module 60, and the post-processing module 70 is configured to be maintained in the vacuum environment. In the present embodiment, a plurality of, for example, six substrate processing modules 60 and a plurality of, for example, two post-processing modules 70 are connected to one vacuum transfer module 50. The number and disposition of the substrate processing modules 60 and the post-processing modules 70 are not limited to the present embodiment and may be set freely.

The vacuum transfer module 50 includes a housing 51 having a planar rectangular shape. As illustrated in FIGS. 3 and 4, the housing 51 is supported by a frame F, and is thus suspended above a floor surface of a room in which the substrate processing system 1 is disposed. Accordingly, a lower space S (see FIG. 3) is formed below the vacuum transfer module 50 as to be described later. Substrate transfer ports 52 to which various modules to be described later are connected are formed in the housing 51. A substrate transfer space in the vacuum transfer module 50 communicates with interiors of the various modules to be described later through the substrate transfer ports 52.

The vacuum transfer module 50 has a first side surface 50a, a second side surface 50b on a side opposite to the first side surface 50a, and a bottom surface 50c. One or more first side surface side modules (first substrate processing modules or first substrate processors) 61, three in the present embodiment, are connected to the first side surface 50a on an X-axis positive direction side of the housing 51. One or more second side surface side modules (second substrate processing modules or second substrate processors) 62, three in the present embodiment, are connected to the second side surface 50b on an X-axis negative direction side of the housing 51. That is, the substrate processing system 1 includes the substrate processing modules, and the substrate processing modules include the first substrate processing modules 61 and the second substrate processing modules 62. The atmospheric transfer module 30 is connected to a front surface of the housing 51 on the Y-axis negative direction side via the load-lock module 20. One or more post-processing modules (other substrate processing modules) 70, two in the present embodiment, are connected to a back surface of the housing 51 on the Y-axis positive direction side. As to be described later, the substrate processing modules 60 include the first side surface side modules 61 and the second side surface side modules 62. Therefore, the vacuum transfer module 50 is connected to one or more substrate processing modules 60. In the vacuum transfer module 50, for example, the substrate W transferred into the load-lock chamber 21a of the load-lock module 20 is sequentially transferred into one substrate processing module 60 and one post-processing module 70 and is processed, and then transferred to the atmospheric portion 10 through the load-lock chamber 21b of the load-lock module 20.

An opening 53 is formed in the bottom surface 50c forming the housing 51. The opening 53 is formed at a position offset from a center of the housing 51 in the X-axis direction and a Y-axis direction. Therefore, a distance D1 from the first side surface 50a of the housing 51 to the opening 53 is larger than a distance D2 from the second side surface 50b of the housing 51 to the opening 53.

The substrate processing system 1 includes a substrate transfer robot 80 disposed inside the vacuum transfer module 50. The substrate transfer robot 80 is configured to transfer the substrate W between the load-lock module 20, the one or more substrate processing modules 60, and the one or more post-processing modules 70. In one embodiment, the substrate transfer robot 80 is detachably attached to the vacuum transfer module 50 to close the opening 53, and is configured to transfer the substrate W in the vacuum transfer module 50. The substrate transfer robot 80 can be taken out from the opening 53 into the lower space S.

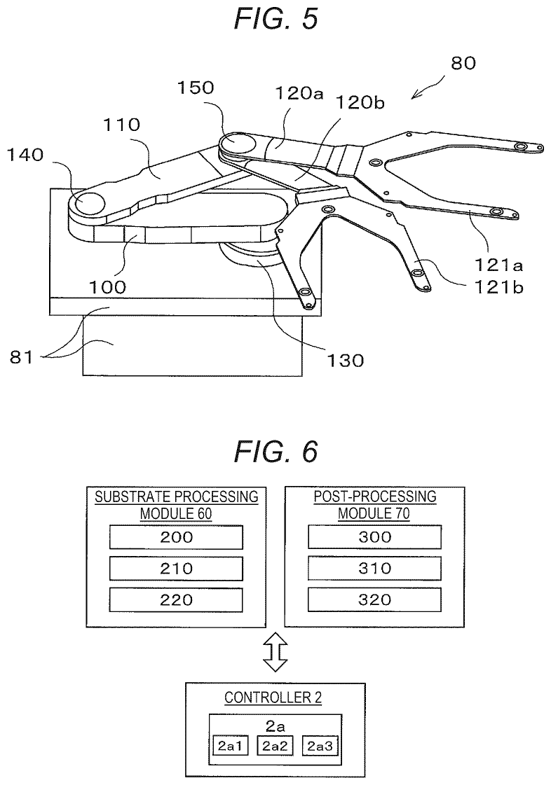

FIG. 5 is a perspective view illustrating a schematic configuration of the substrate transfer robot 80. As illustrated in FIG. 5, the substrate transfer robot 80 includes a first arm 100 having one end rotatably connected to a base 81, a second arm 110 having one end rotatably connected to the other end of the first arm 100, a third arm 120a rotatably connected to the other end of the second arm 110, and a fourth arm 120b rotatably connected to the other end of the second arm 110.

Further, an upper fork 121a and a lower fork 121b for holding the substrate W are connected to the other ends of the third arm 120a and the fourth arm 120b, respectively. The upper fork 121a and the lower fork 121b are disposed to overlap each other in a lengthwise direction with the upper fork 121a on an upper side. Therefore, the substrate transfer robot 80 can transfer two substrates W at the same time in an overlapping manner in the lengthwise direction. The upper fork 121a and the lower fork 121b are configured to be independently rotatable around a vertical axis as to be described later.

The base 81 supports a main body of the substrate transfer robot on an upper surface thereof via a first joint 130 to be described later. In the present embodiment, the main body of the substrate transfer robot includes the first arm 100, the second arm 110, the third arm 120a, the fourth arm 120b, the upper fork 121a, and the lower fork 121b. The base 81 is fitted into the opening 53 formed in the housing 51 described above and connected to the vacuum transfer module 50, and accordingly, the substrate transfer robot 80 supported on the upper surface thereof is loaded into the vacuum transfer module 50. A method for connecting the base 81 to the housing 51 (a method for loading and unloading the substrate transfer robot 80 into and from the vacuum transfer module 50) will be described in detail later.

The first arm 100 is connected to the base 81 via the first joint 130. The first joint 130 is provided with, for example, a rotation mechanism (not illustrated) such as a motor. The substrate transfer robot 80 is configured such that the first arm 100 is rotatable with respect to the base 81 by operating the rotation mechanism by a driving mechanism (not illustrated). The second arm 110 is connected to the first arm 100 via a second joint 140. The second joint 140 is provided with, for example, a rotation mechanism (not illustrated) such as a motor. The substrate transfer robot 80 is configured such that the second arm 110 is rotatable with respect to the first arm 100 by operating the rotation mechanism by a driving mechanism (not illustrated).

The third arm 120a and the fourth arm 120b are connected to the second arm 110 via a third joint 150. The third joint 150 is provided with, for example, a rotation mechanism (not illustrated) such as a motor corresponding to each of the third arm 120a and the fourth arm 120b. The substrate transfer robot 80 is configured such that the third arm 120a and the fourth arm 120b are rotatable independently of each other with respect to the second arm 110 by operating each of the rotation mechanisms by a driving mechanism (not illustrated).

Electrical wirings for supplying power to the rotation mechanism and the driving mechanism disposed inside the first to third joints 130 to 150 are connected to, for example, a power source (not illustrated) through an interior of each arm in an atmospheric pressure atmosphere.

The substrate transfer robot 80 can transfer the substrate W between the load-lock module 20, the substrate processing module 60, and the post-processing module 70 by the relative expansion and contraction rotation of the arms associated with the operations of the rotation mechanism disposed in each joint.

The substrate processing module 60 performs plasma processing such as an etching process on the substrate W. The substrate processing module 60 communicates with the vacuum transfer module 50 through the substrate transfer port 52 formed in a sidewall surface of the vacuum transfer module 50, and the substrate transfer ports 52 are configured to be opened and closed by using gate valves 63. The substrate processing module 60 includes a housing having a vertically long cross-sectional shape that stands upward from the floor surface of the room in which the substrate processing system 1 is disposed (see FIG. 2). For example, a height position of an upper surface of the substrate processing module 60 is larger than a height position of an upper surface of the vacuum transfer module. Therefore, an upper space defined by an upper surface of the housing 51, the first side surface side modules 61, and the second side surface side modules 62 is formed above the vacuum transfer module 50.

The gate valve 63 is connected to a middle stage of the housing in the lengthwise direction, and a plasma processing chamber for performing processing on the substrate W is disposed. The plasma processing chamber has a plasma processing space. Plasma sources for generating a plasma in the substrate processing module 60, or gas supply sources or the like (hereinafter, referred to as “gas boxes or the like”) are disposed in an upper portion of the housing. Electrical wirings or the like (hereinafter, referred to as “electric units” or “electric wirings”) connected to a power source for generating the plasma in the substrate processing module 60 are disposed on a lower portion of the housing.

In the technique of the present disclosure, the gas boxes or the like include first gas boxes or the like corresponding to the first side surface side modules 61, respectively, and second gas boxes or the like corresponding to the second side surface side modules 62, respectively. In the technique of the present disclosure, the electric units include first electric units corresponding to the first side surface side modules 61, respectively, and second electric units corresponding to the second side surface side modules 62, respectively.

In the illustrated example, a case has been described in which the substrate processing module 60 has the housing having a vertically long cross-sectional shape and the plasma processing chamber, the gas boxes or the like, and the electric units are disposed inside one housing forming the substrate processing module 60. However, the plasma processing chamber, the gas boxes or the like, and the electric units may be disposed in different housings, respectively. Therefore, each of the substrate processing modules 60 may have a plasma processing chamber, a corresponding gas box or the like may be disposed above the substrate processing module 60, and a corresponding electric unit may be disposed below the substrate processing module 60. In this case, the gas boxes corresponding to the substrate processing modules 60 may be disposed in the upper space formed above the vacuum transfer module 50 described above.

A configuration of the substrate processing module 60 is not particularly limited.

For example, the substrate processing module 60 includes a plasma processing chamber 200, a substrate support 210, and a plasma generator 220 as illustrated in FIG. 6. The plasma processing chamber 200 has a plasma processing space. The plasma processing chamber 200 has at least one gas supply port for supplying at least one processing gas into the plasma processing space and at least one gas exhaust port for exhausting the gas from the plasma processing space. The gas supply port is connected to a gas supply, and the gas exhaust port is connected to an exhaust system. The substrate support 210 is disposed in the plasma processing space and has a substrate support surface for supporting a substrate.

The plasma generator 220 is configured to generate a plasma from the at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The post-processing module 70 serving as other substrate processing modules performs post-processing on the substrate W after the plasma processing in the substrate processing module 60. In one embodiment, the post-processing module 70 performs ashing using the plasma. The substrate processing module 60 communicates with the vacuum transfer module 50 through the substrate transfer port 52 formed in the sidewall surface of the vacuum transfer module 50, and the substrate transfer ports 52 are configured to be opened and closed by using gate valves 71.

A configuration of the post-processing module 70 is not particularly limited, and in general, in a post-processing step of the substrate W, a large current and a large capacity are not required as compared with the plasma processing such as the etching processing in the substrate processing module 60 described above. Therefore, the post-processing module 70 can be implemented as a plasma processing apparatus smaller than the substrate processing module 60.

For example, the post-processing module 70 includes a plasma processing chamber 300, a substrate support 310, and a plasma generator 320 as illustrated in FIG. 6. For example, the plasma processing chamber 300 has a plasma processing space smaller than that of the substrate processing module 60 (see also FIG. 4). The plasma processing chamber 300 has at least one gas supply port for supplying at least one processing gas into the plasma processing space and at least one gas exhaust port for exhausting the gas from the plasma processing space. The gas supply port is connected to a gas supply, and the gas exhaust port is connected to an exhaust system. The substrate support 310 is disposed in the plasma processing space and has a substrate support surface for supporting a substrate.

For example, the plasma generator 320 has a plasma generation space separated from the plasma processing space (plasma processing chamber 300). Therefore, the post-processing module 70 is implemented as a remote plasma processing apparatus in which the plasma processing space and the plasma generation space are separated. The plasma processing space and the plasma generation space may be formed, for example, by being partitioned by a partition plate inside one housing, or a housing forming the plasma processing space and a housing forming the plasma generation space may be physically separated from each other.

For example, a box 72 in which electrical wirings or the like are accommodated is disposed below the housing (plasma processing space and/or plasma generation space) of the post-processing module 70. For example, the box 72 is disposed below the vacuum transfer module 50 and inside a leg of the frame F that supports the vacuum transfer module 50.

The plasma processing performed on the substrate W in the substrate processing module 60 and the post-processing module 70 is performed, for example, under control of a controller 2 to be described later as also illustrated in FIG. 6.

Returning to the description of the substrate processing system 1.

As illustrated in FIG. 3, the lower space S defined by the bottom surface 50c of the housing 51, the first side surface side modules 61, and the second side surface side modules 62 is formed below the vacuum transfer module 50 in the decompression portion 11. In one embodiment, the lower space S is formed to extend from an end of the vacuum transfer module 50 on the Y-axis negative direction side to an end thereof on the Y-axis positive direction side. The lower space S provides access to the opening 53 formed in the bottom surface 50c of the housing 51 of the vacuum transfer module 50, that is, to the substrate transfer robot 80 disposed in the vacuum transfer module 50. Therefore, the lower space S functions as a workspace for maintenance of the vacuum transfer module 50 and the substrate transfer robot 80, and for loading and unloading the substrate transfer robot 80.

As illustrated in FIG. 3, the electrical wirings or the like disposed in a lower portion of the first side surface side module 61 or the second side surface side module 62 may be disposed in a lower portion SI of the lower space S. In other words, in the lower portion SI of the lower space S, an ineffective space (see a hatched portion in FIG. 3) that cannot be used for loading and unloading the substrate transfer robot 80 may be formed. Therefore, an effective width (first width W1) of the lower portion SI of the lower space S that can be used for loading and unloading the substrate transfer robot 80 is less than an effective width (second width W2) of an upper portion Su of the lower space S.

As described above, the post-processing modules 70, more specifically, the boxes 72 corresponding to the respective post-processing modules 70, are disposed inside the leg of the frame F below the vacuum transfer module 50, as illustrated in FIG. 4. Therefore, the post-processing modules 70, more specifically, the boxes 72 corresponding to the respective post-processing modules 70 define a lower space inlet Se communicating with the lower space S. An effective width (third width W3) of the lower space inlet Se of the lower space S that can be used for loading and unloading the substrate transfer robot 80 is less than the effective width (second width W2) of the upper portion Su of the lower space S described above. The lower space inlet Se of the lower space S has the same effective height H1 as the lower space S.

The substrate processing system 1 described above is provided with the controller 2 as illustrated in FIG. 1. The controller 2 processes computer-executable instructions for causing the substrate processing system 1 to execute various processes to be described in the present disclosure. The controller 2 may be configured to control the elements of the substrate processing system 1 to execute various steps described herein. In one embodiment, a part or all of the controller 2 may be included in the substrate processing system 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the substrate processing system 1 via a communication line such as a local area network (LAN). Further, the storage medium may be temporary or non-temporary medium. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

Next, a method for transferring the substrate transfer robot 80 to the vacuum transfer module 50 in the substrate processing system 1 implemented as described above will be described in detail with reference to the drawings.

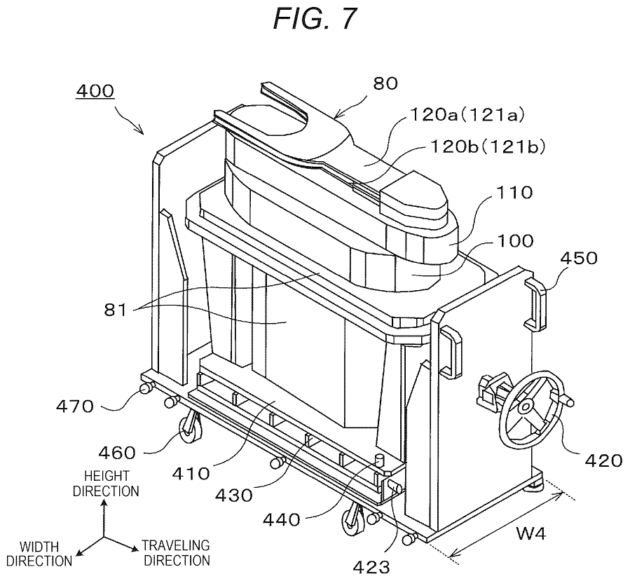

When the substrate transfer robot 80 is transferred to the vacuum transfer module 50, first, the substrate transfer robot 80 which is a transfer target is placed on a trolley 400 as illustrated in FIG. 7. As illustrated in FIG. 7, the trolley 400 includes a supporting plate 410 that supports the substrate transfer robot 80 which is a transfer target on an upper surface thereof, a vertical driving unit 420 (i.e., vertical driver) that moves the substrate transfer robot 80 on the supporting plate 410 in a vertical direction (lengthwise direction), a horizontal driving unit 430 (i.e. horizontal driver) that moves the substrate transfer robot 80 on the supporting plate 410 in the horizontal direction (lateral direction), and an alignment mechanism 440. The trolley 400 may further include a handle 450 for an operator to handle the trolley 400, a caster 460 for moving the trolley 400 in the horizontal direction, and a mechanism 470 for preventing the trolley 400 from falling. Further, the trolley 400 has a fourth width W4 less than the effective width (third width W3) of the lower space inlet Se in a width direction orthogonal to a traveling direction. Therefore, the trolley 400 can enter the lower space S of the vacuum transfer module 50 through the lower space inlet Se. Specific operations of the respective elements forming the trolley 400 will be described later.

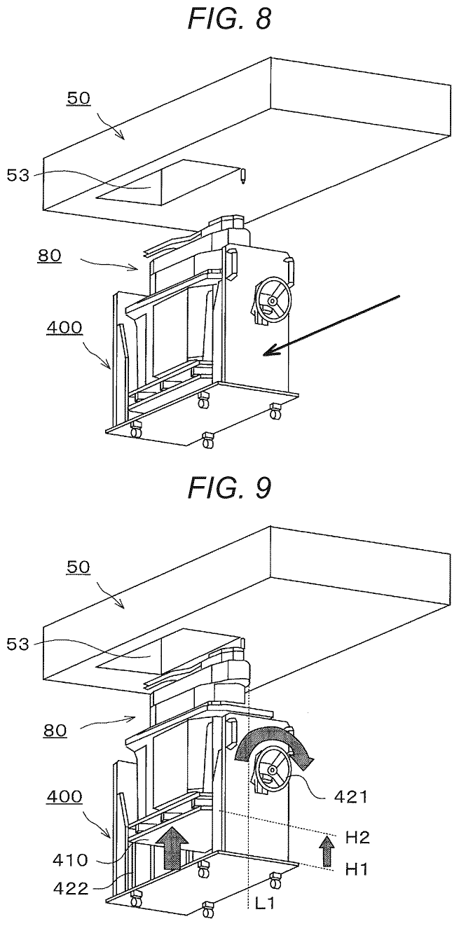

When the substrate transfer robot 80 is placed on the trolley 400, next, the trolley 400 is moved to the lower space S of the vacuum transfer module 50, more specifically, below the opening 53 as illustrated in FIG. 8. For example, the trolley 400 may be moved by the operator by holding the handle 450, or may be moved by a remote operation. At this time, since the trolley 400 has the fourth width W4 less than the third width W3 of the lower space inlet Se, the trolley 400 can appropriately enter the lower space S of the vacuum transfer module 50 (entering step).

When the substrate transfer robot 80 is moved below the opening 53, next, the substrate transfer robot 80 on the supporting plate 410 is moved in the vertical direction (lengthwise direction) by using the vertical driving unit 420 as illustrated in FIG. 9. A configuration and an operation of the vertical driving unit 420 are not particularly limited. In the illustrated example, the vertical driving unit 420 includes an elevating handle 421, a vertical axis rail 422, and a vertical movement stopper 423 (see FIG. 7). Then, after the vertical movement stopper 423 is released to allow the supporting plate 410 to be elevated, the supporting plate 410 and the substrate transfer robot 80 are integrally raised along the vertical axis rail 422 by operating the elevating handle 421 (first raising step).

An amount by which the substrate transfer robot 80 is raised in the first raising step is not particularly limited, and for example, in the first raising step, it is preferable to raise the substrate transfer robot 80 (the supporting plate 410) to a height at which the ineffective space illustrated by the hatched portion in FIG. 3 can be avoided. Therefore, the present first raising step can be said to be a step for preventing interference between the substrate transfer robot 80 (the supporting plate 410) and the electrical wirings or the like of the first side surface side module 61 and the second side surface side module 62 disposed in the lower portion SI of the lower space S. For example, in the first raising step, the supporting plate 410 is raised from a first plate height H1 to a second plate height H2 at a first horizontal position L1 by the vertical driving unit 420. Therefore, when the electrical wirings or the like of the first side surface side module 61 and the second side surface side module 62 are not disposed in the lower space S (when the ineffective space of FIG. 3 is not formed), the present first raising step may be omitted.

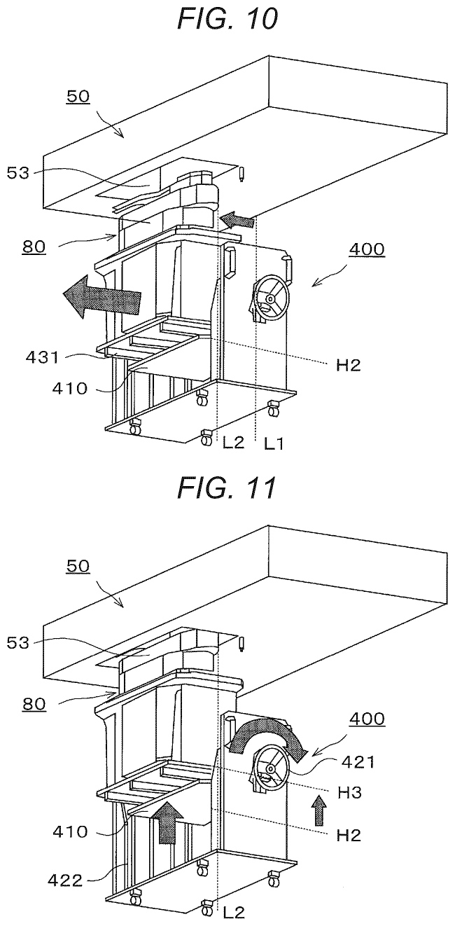

When the supporting plate 410 is raised to the second plate height H2, then, as illustrated in FIG. 10, the supporting plate 410 is moved in the horizontal direction from the first horizontal position L1 to a second horizontal position L2 immediately below the opening 53 at the second plate height H2 by the horizontal driving unit 430. A configuration and an operation of the horizontal driving unit 430 are not particularly limited. In the illustrated example, the horizontal driving unit 430 includes a horizontal axis rail 431 and a horizontal moving handle (not illustrated). Then, the substrate transfer robot 80 raised to the second plate height is moved integrally with the supporting plate 410 along the horizontal axis rail 431 by, for example, an operation of the horizontal moving handle (horizontal moving step). The horizontal movement of the substrate transfer robot 80 (supporting plate 410) may be performed manually instead of operating the horizontal moving handle.

As described above, the opening 53 of the vacuum transfer module 50 into which the substrate transfer robot 80 is fitted is formed at a position deviated from the center of the housing 51 in the X-axis direction (width direction), more specifically, at a position at which the distance D1 from the first side surface 50a of the housing 51 is larger than the distance D2 from the second side surface 50b. As described above, the electric units of the substrate processing module 60 may be disposed in the lower space S of the vacuum transfer module 50.

In the technique according to the present disclosure, the supporting plate 410 of the trolley 400 that transfers the substrate transfer robot 80 is configured to be movable in the horizontal direction by the horizontal driving unit 430 as described above. Accordingly, even when trolley 400 cannot be moved immediately below the opening 53, the substrate transfer robot 80 can be moved immediately below the opening 53 by horizontally offsetting the supporting plate 410 in the horizontal direction. At this time, even when the electric units of the substrate processing module 60 are disposed in the lower space S of the vacuum transfer module 50, the interference between the electric units of the substrate processing module 60 and the substrate transfer robot 80 (supporting plate 410) can be prevented by moving the substrate transfer robot 80 in the horizontal direction after the substrate transfer robot 80 (supporting plate 410) is raised to the second plate height H2 in the first raising step described above.

When the supporting plate 410 is moved to the second horizontal position L2, then, the supporting plate 410 is raised from the second plate height H2 to a third plate height H3 at the second horizontal position L2 by the vertical driving unit 420 as illustrated in FIG. 11 (second raising step). A method for driving the vertical driving unit 420 is the same as that in the first raising step described above.

In the second raising step, for example, the supporting plate 410 is raised from the second plate height H2 described above to the third plate height H3 at which alignment can be performed by a guide pins 54 (see FIG. 11) provided at a bottom of the housing 51 of the vacuum transfer module 50. In the illustrated example, only one guide pin 54 is disposed at the bottom of the housing 51. The number of guide pins 54 disposed on the housing 51 can be freely determined, and is preferably two or more.

When the supporting plate 410 is raised to the third plate height H3, then, the substrate transfer robot 80 supported by the supporting plate 410 is subjected to accurate alignment of a horizontal direction position by using the alignment mechanism 440 as illustrated in FIG. 12. A configuration of the alignment mechanism 440 is not particularly limited, and for example, the alignment mechanism 440 includes a plunger pin 441. Then, by opening the plunger pin 441, the accurate alignment in the horizontal direction of the substrate transfer robot 80 on the supporting plate 410 by the alignment mechanism 440 is enabled, and accordingly, the substrate transfer robot 80 is moved to a position at which the substrate transfer robot 80 can be attached to the opening 53.

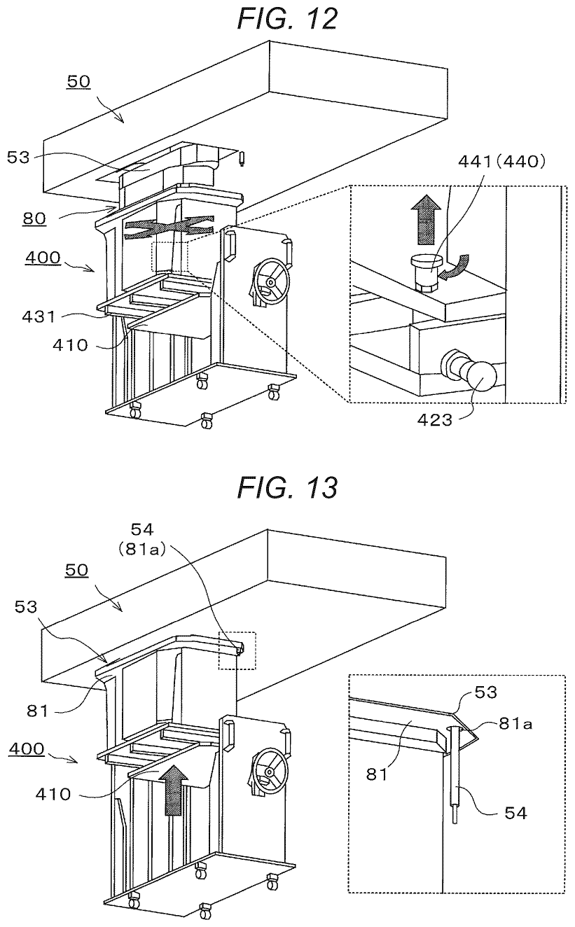

As illustrated in FIG. 13, for example, the accurate alignment of the substrate transfer robot 80 with respect to the opening 53 can be implemented by inserting the guide pin 54 provided at the bottom of the housing 51 into a through-hole 81a for alignment formed in the base 81 that supports the substrate transfer robot 80 by raising the substrate transfer robot 80 (via supporting plate 410) by the operation of the vertical driving unit 420 while aligning the guide pin 54 with the through-hole 81a.

When the guide pin 54 is inserted into the through-hole 81a, the substrate transfer robot 80 (base 81) is then fixed to the housing 51 of the vacuum transfer module 50, and accordingly, a loading operation of the substrate transfer robot 80 into the vacuum transfer module 50 is completed. Therefore, the substrate transfer robot 80, supported by the supporting plate 410, is attached to the opening 53 of the vacuum transfer module 50 when the supporting plate 410 is located at the second horizontal position L2 and the third plate height H3.

When the substrate transfer robot 80 is unloaded from the vacuum transfer module 50, the load operations described above with reference to FIGS. 8 to 13 are performed in a reverse order.

Therefore, the supporting plate 410 is lowered from the third plate height H3 to the second plate height H2 at the second horizontal position L2 by the vertical driving unit 420. Accordingly, the substrate transfer robot 80 is taken out from the opening 53 of the vacuum transfer module 50 into the lower space S in a state of being supported by the supporting plate 410. Thereafter, the supporting plate 410 is moved from the second horizontal position L2 to the first horizontal position L1 at the second plate height H2 by the horizontal driving unit 430. Then, the supporting plate 410 is lowered from the second plate height H2 to the first plate height H1 at the first horizontal position L1 by the vertical driving unit 420.

When the supporting plate 410 is lowered to the first plate height H1, the trolley 400 is unloaded from the lower space S of the vacuum transfer module 50 through the lower space inlet Se. Therefore, the substrate transfer robot 80 supported by the supporting plate 410 is unloaded from the lower space S of the vacuum transfer module 50 when the supporting plate 410 is located at the first horizontal position L1 and the first plate height H1.

As described above, in the substrate processing system 1 according to the technique of the present disclosure, the lower space S is formed below the vacuum transfer module 50, and the opening 53 into which the substrate transfer robot 80 is to be fitted is formed in the bottom surface 50c of the housing 51, thereby providing access to the vacuum transfer module 50 from below during the maintenance of the vacuum transfer module 50 or the substrate transfer robot 80 or when loading and unloading the substrate transfer robot 80. Accordingly, the maintenance of the substrate transfer robot 80, which is heavy, becomes easier than in the related art.

In the technique according to the present disclosure, the trolley 400 that can move in the horizontal direction and elevate the substrate transfer robot 80 on the supporting plate 410 is used when the substrate transfer robot 80 is loaded and unloaded into and from the vacuum transfer module 50. Accordingly, the substrate transfer robot 80 can be more easily loaded and unloaded into and from the vacuum transfer module 50, and the substrate transfer robot 80 can be appropriately loaded and unloaded into and from the vacuum transfer module 50 even when the electric units of the substrate processing module 60 are disposed in the lower space S of the vacuum transfer module 50.

When the substrate transfer robot 80 is loaded and unloaded into and from the substrate transfer robot 80 using the trolley 400 according to the technique of the present disclosure, the stability during the raising and the horizontal movement of the supporting plate 410 is improved using the mechanism 470 mounted on the trolley 400. For example, the mechanism 470 includes a first slider disposed on a side surface of the trolley 400 on a side of the first side surface module 61, and a second slider disposed on a side surface of the trolley 400 on a side of the second side surface module 62.

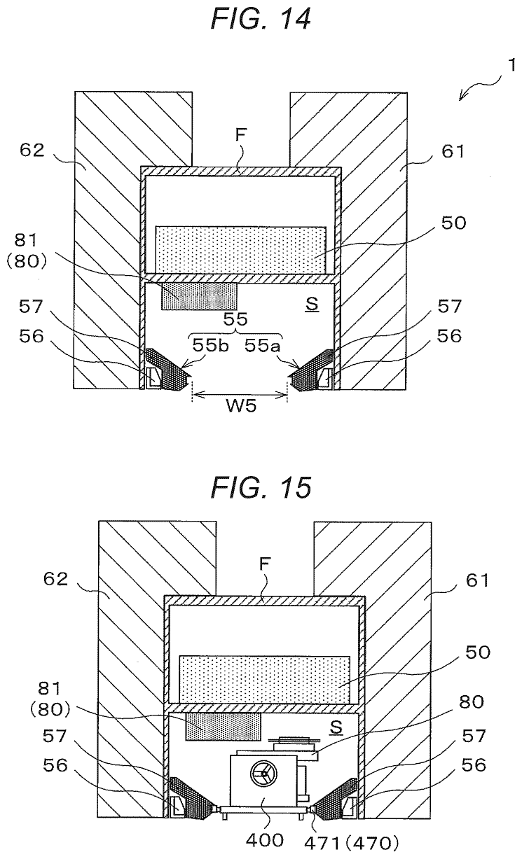

Specifically, as illustrated in FIG. 14, a jig 55 is attached to the leg of the frame F that supports the housing 51 of the vacuum transfer module 50, before the trolley 400 on which the substrate transfer robot 80 is placed enters the lower space S (entering step). The jig 55 includes a first jig 55a fixed to the leg of the frame F on the side of the first side surface side module 61 and a second jig 55b fixed to the leg of the frame F on the side of the second side surface side module 62 in the lower space S. Each of the first jig 55a and the second jig 55b includes a rail 56 and a bracket 57. The rail 56 is disposed to extend in the Y-axis direction (longitudinal direction of the vacuum transfer module 50) in the lower space S and is fixed to the leg of the frame F. The bracket 57 is a member disposed at a plurality of locations spaced apart from the rail 56 in the longitudinal direction and engages with a slider 471 of the mechanism 470 to be described later to improve the stability of the trolley 400. As illustrated in FIG. 14, a distance (fifth width W5) between the first jig 55a and the second jig 55b in the X-axis direction (width direction of the vacuum transfer module 50) is set to be the same as, or slightly less than the fourth width W4 of the trolley 400. Therefore, the trolley 400 can be moved in the Y-axis direction in the lower space S through a space between the first jig 55a and the second jig 55b.

In the technique according to the present disclosure, the bracket 57 may be included in the rail 56 and referred to as a “rail” of the jig 55. In other words, the slider 471 of the mechanism 470 engages with the rail of the jig 55. Therefore, the mechanism 470 includes at least one first slider that engages with the first rail on the side of the first side surface side module 61 and is slidable along the first rail, and at least one second slider that engages with the second rail on the side of the second side surface side module 62 side and is slidable along the second rail.

When the attachment of the jig 55 to the frame F is completed, the trolley 400 enters the lower space S (entering step). At this time, as illustrated in FIG. 15, the mechanism 470 of the trolley 400 is engaged with a recess formed in the bracket 57 of the rail 56 fixedly disposed in the frame F. As described above, the brackets 57 are provided in the longitudinal direction of the rail 56, and accordingly, the mechanism 470 of the trolley 400 and the jig 55 of the vacuum transfer module 50 are engaged with each other. Therefore, the trolley 400 is supported by the frame F from both sides in the width direction, and the stability is improved even when some stress acts on the trolley 400.

It shall be understood that the embodiments disclosed herein are illustrative and are not restrictive in all aspects. The embodiment described above may be omitted, replaced, or modified in various forms without departing from the scope and spirit of the appended claims.

1. A substrate processing system comprising:
a vacuum transferer extending along a longitudinal direction of the substrate processing system, the vacuum transferer having a first side surface, a second side surface on a side opposite to the first side surface, and a bottom surface, the bottom surface having an opening, a distance from the opening to the first side surface being larger than a distance from the opening to the second side surface,
substrate processors including first substrate processors connected to the first side surface of the vacuum transferer and second substrate processors connected to the second side surface of the vacuum transferer,
a lower space defined between the first substrate processors and the second substrate processors below the vacuum transferer,
a transfer robot detachably attached to the vacuum transferer to close the opening the opening of the vacuum transferer, configured to transfer a substrate in the vacuum transferer, and configured to be taken out from the opening into the lower space,
a first rail attached to the first substrate processors to extend along the longitudinal direction in the lower space, and
a second rail attached to the second substrate processors to extend along the longitudinal direction in the lower space.

2. The substrate processing system according to claim 1, wherein
the lower space has a lower portion and an upper portion,
the lower portion has a first width in a width direction orthogonal to the longitudinal direction of the vacuum transferer, and
the upper portion has a second width larger than the first width in the width direction.

3. The substrate processing system according to claim 2, further comprising:
a load-lock connected to a front surface of the vacuum transferer, and
one or more other substrate processors connected to a back surface of the vacuum transferer and configured to define a lower space inlet communicating with the lower space.

4. The substrate processing system according to claim 3, wherein
the lower space inlet has a third width less than the second width in the width direction.

5. The substrate processing system according to claim 4, wherein
the lower space inlet has a height same as a height of the lower space.

6. The substrate processing system according to claim 1, further comprising:
first electric wirings, each first electric wiring corresponding to a respective one of the first substrate processors; and
second electric wirings, each second electric wiring corresponding to a respective one of the second substrate processors.

7. The substrate processing system according to claim 6, further comprising:
gas boxes including:
first gas boxes, each first gas box corresponding to a respective one of the first substrate processors; and
second gas boxes, each second gas box corresponding to a respective one of the second substrate processors.

8. The substrate processing system according to claim 7, wherein
each first electric wiring is disposed below the respective first substrate processor, and
each second electric wiring is disposed below the respective second substrate processor.

9. The substrate processing system according to claim 8, wherein
each first gas box is disposed above the respective first substrate processor, and
each second gas box is disposed above the respective second substrate processor.

10. The substrate processing system according to claim 1, further comprising:
an upper space defined between the first substrate processors and the second substrate processors above the vacuum transferer.

11. The substrate processing system according to claim 10, wherein
a height of an upper surface of the vacuum transferer is less than a height of an upper surface of the substrate processor.

12. The substrate processing system according to claim 1, wherein
the vacuum transferer includes a plurality of guide pins for aligning the transfer robot to the vacuum transferer.

13. A trolley for carrying the transfer robot to the substrate processing system according to claim 1, the trolley comprising:
at least one first slider engageable with the first rail and slidable along the first rail,
at least one second slider engageable with the second rail and slidable along the second rail,
a supporting plate configured to support the transfer robot,
a vertical driver configured to raise the supporting plate from a first plate height to a second plate height at a first horizontal position, and
a horizontal driver configured to move the supporting plate from the first horizontal position to a second horizontal position at the second plate height, wherein
the vertical driver is further configured to raise the supporting plate from the second plate height to a third plate height at the second horizontal position, and
the transfer robot supported by the supporting plate is attached to the opening of the vacuum transferer when the supporting plate is at the second horizontal position and the third plate height.

14. The trolley according to claim 13, wherein
the vertical driver is configured to lower the supporting plate from the third plate height to the second plate height at the second horizontal position, and accordingly, the transfer robot supported by the supporting plate is taken out from the vacuum transferer into the lower space,
the horizontal driver is configured to move the supporting plate from the second horizontal position to the first horizontal position at the second plate height, and
the vertical driver is configured to lower the supporting plate from the second plate height to the first plate height at the first horizontal position.

15. The trolley according to claim 13, wherein
the trolley has a fourth width less than a width of an inlet of the lower space in the width direction of the vacuum transferer.

16. A substrate processing system comprising:
a vacuum transferer extending along a longitudinal direction of the substrate processing system, the vacuum transferer having a first side surface, a second side surface on a side opposite to the first side surface, and a bottom surface with an opening,
a load-lock connected to a front surface of the vacuum transferer;
substrate processors including first substrate processors connected to the first side surface of the vacuum transferer and second substrate processors connected to the second side surface of the vacuum transferer,
a lower space defined between the first substrate processors and the second substrate processors below the vacuum transferer,
a transfer robot detachably attached to the vacuum transferer to close the opening of the vacuum transferer, the transfer robot being configured to transfer a substrate between the load-lock and the substrate processors in the vacuum transferer,
a first rail attached to the first substrate processors to extend along the longitudinal direction in the lower space, and
a second rail attached to the second substrate processors to extend along the longitudinal direction in the lower space.

17. The substrate processing system according to claim 16, wherein the transfer robot includes:
a first arm having a first end rotatably connected to a base and a second end;
a second arm having a first end rotatably connected to the second end of the first arm and a second end;
a third arm rotatably connected to the second end of the second arm; and
a fourth arm rotatably connected to the second end of the second arm.

18. The substrate processing system according to claim 16, further comprising:
post-processors for performing post-processing on the substrate, wherein
an interior of each of the vacuum transferer, the substrate processors, and the post-processors is configured to be maintained in a vacuum environment.

19. The substrate processing system according to claim 16, further comprising:
one or more other substrate processors connected to a back surface of the vacuum transferer and configured to define a lower space inlet communicating with the lower space.

20. The substrate processing system according to claim 19, wherein
the lower space inlet has a third width less than the second width in the width direction, and
the lower space inlet has a height same as a height of the lower space.
